(19) United States
(12) Patent Application Publication
(10) Pub. No.: US 2019/0207019 A1
(43) Pub. Date: Jul. 4, 2019

(54) ENHANCEMENT MODE HEMT DEVICE

(71) Applicant: Nuvoton Technology Corporation, Hsinchu (TW)

(72) Inventors: Jung-Tse Tsai, Hsinchu (TW); Heng-Kuang Lin, Hsinchu (TW)

(73) Assignee: Nuvoton Technology Corporation, Hsinchu (TW)

(21) Appl. No.: 16/191,476

(22) Filed: Nov. 15, 2018

(30) Foreign Application Priority Data
Dec. 28, 2017 (TW) 106146140

(51) Int. Cl. H01L 29/778; H01L 29/423

(52) U.S. Cl. CPC H01L 29/7786; H01L 29/42316

(57) ABSTRACT

Provided is an enhancement mode HEMT device including a substrate, a channel layer, a first barrier layer, a gate, a source and a drain. The channel layer is disposed on the substrate. The first barrier layer is disposed on the channel layer. At least one trench penetrates through the first barrier layer and extends into the channel layer. The gate is disposed on the first barrier layer, fills in the at least one trench and is in contact with the channel layer. The source and the drain are disposed in the first barrier layer and the channel layer and located at two sides of the gate.

### CROSS-REFERENCE TO RELATED APPLICATION

This application claims the priority benefit of Taiwan application no. 106146140, filed on Dec. 28, 2017. The entirety of the above-mentioned patent application is hereby incorporated by reference herein and made a part of this specification.

### BACKGROUND OF THE INVENTION

### Field of Invention

The present invention relates to a semiconductor device, and more generally to an enhancement mode high electron mobility transistor (HEMT) device.

### Description of Related Art

In recent years, group III-V compound semiconductor based HEMT devices have been widely applied in high power electronic devices due to their low resistance, high breakdown voltage and fast switch speed, etc.

HEMT devices can be divided into depletion mode or normally on transistor devices, and enhancement mode or normally off transistor devices. The enhancement mode transistor devices have been drawn high attention in the industry because of the added safety and because they are easier to control with simple and low cost drive circuits. In an enhancement mode transistor device, an embedded gate is limited by the need to precisely control the etching depth and the instability of the etching process, resulting in a higher initial voltage and a higher turn-on channel resistance.

### SUMMARY OF THE INVENTION

Accordingly, the present invention provides an enhancement mode HEMT device, in which the electrical difference caused by unstable etching is improved, and the turn-on channel resistance of the device is reduced.

The present invention provides an enhancement mode HEMT device that includes a substrate, a channel layer, a first barrier layer, a gate, a source and a drain. The channel layer is disposed on the substrate. The first barrier layer is disposed on the channel layer. At least one trench penetrates through the first barrier layer and extends into the channel layer. The gate is disposed on the first barrier layer, fills in the at least one trench and is in contact with the channel layer. The source and the drain are disposed in the first barrier layer and the channel layer and located at two sides of the gate.

According to an embodiment of the present invention, the enhancement mode HEMT device further includes a negatively charged region disposed in the channel layer and surrounding a sidewall and a bottom of the at least one trench.

According to an embodiment of the present invention, the negatively charged region includes fluorine ions.

According to an embodiment of the present invention, the enhancement mode HEMT device further includes a passivation layer disposed between the gate and the first barrier layer.

According to an embodiment of the present invention, the passivation layer includes silicon oxide, silicon nitride, silicon oxynitride or a combination thereof.

According to an embodiment of the present invention, the gate includes a lower gate disposed in the at least one trench, and an upper gate disposed on the lower gate, wherein a dielectric layer is disposed between the lower gate and the upper gate.

According to an embodiment of the present invention, the enhancement mode HEMT device further includes a second barrier layer disposed in the at least one trench and surrounded by the lower gate.

According to an embodiment of the present invention, the second barrier layer has a zinc blende structure.

According to an embodiment of the present invention, the second barrier layer includes AlₓGa_{y}In_{1-x-y}N, x≥0, y≥0, and x+y≤1.

According to an embodiment of the present invention, the dielectric layer includes aluminum oxide.

According to an embodiment of the present invention, the dielectric layer is further disposed between the upper gate and the first barrier layer.

According to an embodiment of the present invention, the enhancement mode HEMT device further includes a passivation layer disposed between the dielectric layer and the first barrier layer.

According to an embodiment of the present invention, the at least one trench includes two trenches separated from each other, and a distance between the two trenches is less than or equal to about 1 μm.

According to an embodiment of the present invention, the enhancement mode HEMT device further includes a negatively charged region disposed in the channel layer between the two trenches.

The present invention further provides an enhancement mode HEMT device that includes a substrate, a channel layer, a first barrier layer, a gate, a second barrier layer, a source and a drain. The channel layer is disposed on the substrate. The first barrier layer is disposed on the channel layer. At least one trench penetrates through the first barrier layer and extends into the channel layer. The gate is disposed on the first barrier layer and fills in the at least one trench. The second barrier layer is disposed between the gate and the channel layer. The source and the drain are disposed in the first barrier layer and the channel layer and located at two sides of the gate.

According to an embodiment of the present invention, the second barrier layer has a zinc blende structure.

According to an embodiment of the present invention, the second barrier layer has a wurtzite structure.

According to an embodiment of the present invention, the second barrier layer is negatively charged.

According to an embodiment of the present invention, the second barrier layer is not charged.

According to an embodiment of the present invention, the gate includes a lower gate disposed in the at least one trench, and an upper gate disposed on the lower gate, wherein a dielectric layer is disposed between the lower gate and the upper gate.

In view of the above, in some embodiments, a gate is designed to be in physical contact with a channel layer in an enhancement mode HEMT device. Specifically, the turn-on current of the enhancement mode HEMT device is conducted through the gate, so as to improve the electrical difference caused by unstable etching and therefore reduce the turn-on channel resistance of the device. In alternative embodiments, a negatively charged region, a non-polar structure or a high barrier material is disposed aside a lower gate in another enhancement mode HEMT device, and such disposition can significantly increase the threshold voltage and effectively reduce the leakage current.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1D are schematic cross-sectional views of a method of forming an enhancement mode HEMT device according to an embodiment of the present invention.

FIG. 2 is a schematic cross-sectional view of an enhancement mode HEMT device according to an embodiment of the present invention.

FIG. 3A to FIG. 3C are schematic cross-sectional views of a method of forming an enhancement mode HEMT device according to another embodiment of the present invention.

FIG. 4 is a schematic cross-sectional view of an enhancement mode HEMT device according to another embodiment of the present invention.

FIG. 5A to FIG. 5E are schematic cross-sectional views of a method of forming an enhancement mode HEMT device according to yet another embodiment of the present invention.

FIG. 6 is a schematic cross-sectional view of an enhancement mode HEMT device according to yet another embodiment of the present invention.

FIG. 7A to FIG. 7F are schematic cross-sectional views of a method of forming an enhancement mode HEMT device according to still another embodiment of the present invention.

FIG. 8A to FIG. 8D are schematic cross-sectional views of a method of forming an enhancement mode HEMT device according to an embodiment of the present invention.

FIG. 9 is a schematic cross-sectional view of an enhancement mode HEMT device according to an embodiment of the present invention.

FIG. 10 is a schematic cross-sectional view of an enhancement mode HEMT device according to another embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

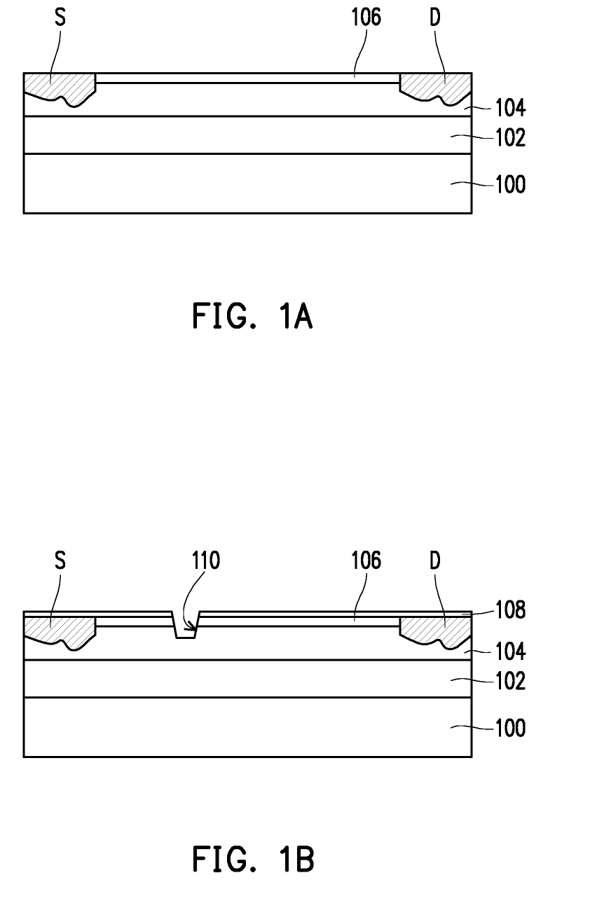

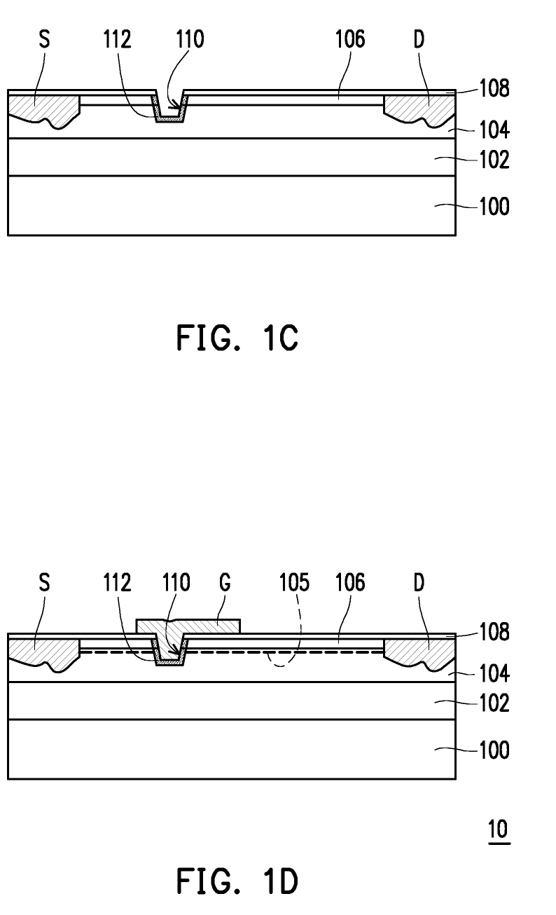

FIG. 1A to FIG. 1D are schematic cross-sectional views of a method of forming an enhancement mode HEMT device according to an embodiment of the present invention.

Referring to FIG. 1A, a channel layer 104 and a barrier layer 106 are sequentially formed on a substrate 100. In an embodiment, the substrate 100 includes sapphire, Si, SiC or GaN. In an embodiment, the channel layer 104 includes a group III nitride or a group III-V compound semiconductor material. For example, the channel layer 104 includes GaN. Besides, the channel layer 104 can be a doped or undoped layer. In an embodiment, the method of forming the channel layer 104 includes performing an epitaxial growth process.

In an embodiment, a buffer layer 102 is optionally formed between the substrate 100 and the channel layer 104. The buffer layer 102 is configured to alleviate a lattice constant difference and a thermal expansion coefficient difference between the substrate 100 and the channel layer 104. In an embodiment, the buffer layer 102 includes a group III nitride or a group III-V compound semiconductor material. For example, the buffer layer 102 includes AlInGaN, AlGaN, AlInN, InGaN, AlN, GaN or a combination thereof. Besides, the buffer layer 102 can have a single-layer or multi-layer structure. In an embodiment, the method of forming the buffer layer 102 includes performing an epitaxial growth process.

In an embodiment, the barrier layer 106 includes a group III nitride or a group m-V compound semiconductor material. For example, the barrier layer 106 includes AlInGaN, AlGaN, AlInN, AlN or a combination thereof. In an embodiment, the barrier layer 106 includes AlₓGa_{y}In_{1-x-y}N, x≥0, y≥0, and x+y≤1. In an embodiment, the barrier layer 106 has a zinc blende structure or a non-polar structure. In another embodiment, the barrier layer 106 has a wurtzite structure or a polar structure. In an embodiment, the method of forming the barrier layer 106 includes performing an epitaxial growth process.

Continue referring to FIG. 1A, a source S and a drain D are formed in the barrier layer 106 and the channel layer 104. In an embodiment, the source S and the drain D are formed to penetrate through the barrier layer 106 and a portion of channel layer 104. In an embodiment, the source S and the drain D include a metal (such as Al, Ti, Ni, Au or an alloy thereof), or a material which can form an Ohmic contact with a group III-V compound semiconductor.

In an embodiment, the method of forming the source S and the drain D includes forming openings in the barrier layer 106 and the channel layer 104, filling an Ohmic metal layer in the openings and performing a tempering process.

Referring to FIG. 1B, a passivation layer 108 is formed on the barrier layer 106. In an embodiment, the passivation layer 108 includes silicon oxide, silicon nitride, silicon oxynitride or a combination thereof. Besides, the passivation layer 108 can have a single-layer or multi-layer structure. In an embodiment, the method of forming the passivation layer 108 includes performing a suitable deposition process, such as a chemical vapour deposition (CVD) process.

Thereafter, a trench 110 is formed in the passivation layer 108, the barrier layer 106 and the channel layer 104. In an embodiment, the trench 110 penetrates through the passivation layer 108 and the barrier layer 106, and extends into a portion of channel layer 104. Besides, the trench 110 can have an inclined sidewall or a substantially vertical sidewall. In an embodiment, the method of forming the trench 110 includes performing a patterning process (e.g., photolithography etching processes) to the passivation layer 108, the barrier layer 106 and the channel layer 104.

Referring to FIG. 1C, a negatively charged region 112 is formed in the channel layer 104, and surrounds the sidewall and the bottom of the trench 110. In an embodiment, the portion of channel layer 104 adjacent to the sidewall and the bottom of the trench 110 is negatively charged. In other words, the negatively charged region 112 is regarded as a part of the channel layer 104. In an embodiment, the negatively charged region 112 is further formed in the barrier layer 106; that is, the portion of the barrier layer 106 adjacent to the trench 110 is negatively charged. In an embodiment, the method of forming the negatively charged region 112 includes performing an ion implantation process, wherein the implanting ions include fluorine ions.

Referring to FIG. 1D, a gate G is formed on the passivation layer 108 and fills in trench 110. In an embodiment, the gate G includes a lower gate inside of the trench 110 and an upper gate outside of the trench 110, and the width of the lower gate is less than the width of the upper gate. The width of the lower gate ranges from about 1 nm to about 10 μm, such as from about 0.1 μm to about 5 μm. In an embodiment, the lower gate is in contact with a two-dimensional electron gas (2DEG) 105 in the channel layer 104, and surrounded by the negatively charged region 112 in the channel layer 104. In an embodiment, the gate electrode G includes a metal or a metal nitride (such as Ta, TaN, Ti, TiN, W, Pd, Ni, Au, Al or a combination thereof), a metal silicide (such as WSiₓ), or a material which can form a Schottky contact with a group III-V compound semiconductor. In an embodiment, the method of forming the gate G includes forming a gate material layer on the passivation layer 108, and performing a patterning process (e.g., photolithography etching processes) to the gate material layer. An enhancement mode HEMT device 10 of the present invention is thus completed.

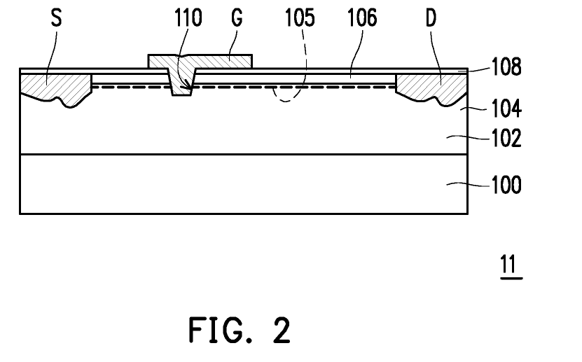

In an embodiment, an enhancement mode HEMT device 11 is formed when the step of forming the negatively charged region 112 is omitted from the above method upon the process requirements, as shown in FIG. 2.

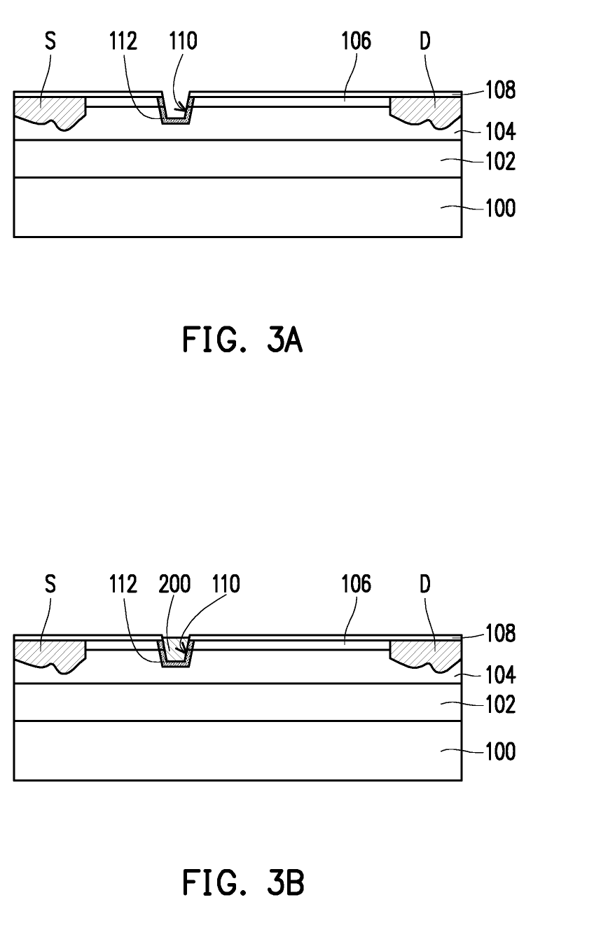

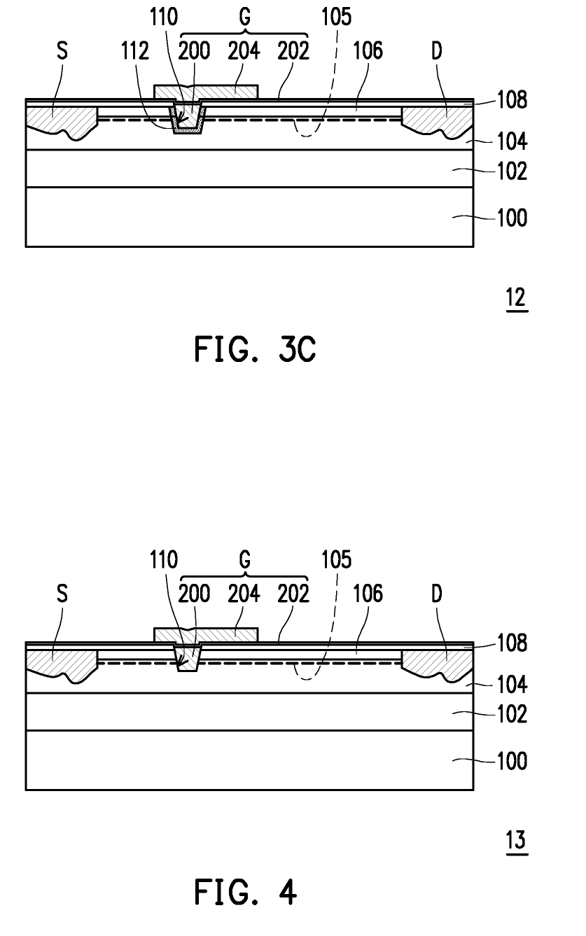

FIG. 3A to FIG. 3C are schematic cross-sectional views of a method of forming an enhancement mode HEMT device according to another embodiment of the present invention.

Referring to FIG. 3A, a structure of FIG. 1C is provided. Referring to FIG. 3B, a lower gate 200 is formed in the trench 110. In an embodiment, the lower gate 200 includes a metal or a metal nitride (such as Ta, TaN, Ti, TiN, W, Pd, Ni, Au, Al or a combination thereof), a metal silicide (such as WSiₓ), or a material which can form a Schottky contact with a group III-V compound semiconductor. In an embodiment, the method of forming the lower gate 200 includes forming a lower gate material layer on the passivation layer 108, and the lower gate material layer completely fills the trench 110. Thereafter, a chemical mechanical polishing (CMP) process is performed by using the passivation layer 108 as a polishing mask, so as to remove the lower gate material layer outside of the trench 110. In an embodiment, the surface of the lower gate 200 is lower than the surface of the passivation layer 108.

Referring to FIG. 3C, a dielectric layer 202 is optionally formed on the passivation layer 108. In an embodiment, the dielectric layer 202 not only covers the surface of the passivation layer 108, but also covers the surface of the lower gate 200. In an embodiment, the dielectric layer 202 includes aluminum oxide. Besides, the dielectric layer 202 can have a single-layer or multi-layer structure. In an embodiment, the method of forming the dielectric layer 202 includes performing a suitable deposition process, such as a CVD process or an atomic layer deposition (ALD) process.

Thereafter, an upper gate 204 is formed on the dielectric layer 202. In an embodiment, the upper gate 204 includes a metal or a metal nitride (such as Ta, TaN, Ti, TiN, W, Pd, Ni, Au, Al or a combination thereof), a metal silicide (such as WSiₓ), or a material which can form a Schottky contact with a group III-V compound semiconductor. In an embodiment, the method of forming the upper gate 204 includes forming an upper gate material layer on the dielectric layer 202, and performing a patterning process (e.g., photolithography etching processes) to the upper gate material layer. In an embodiment, the upper gate 204, the dielectric layer 202 and the lower gate 200 constitute a gate G, wherein the lower gate 200 is in contact with the 2DEG 105 in the channel layer 104 and surrounded by the negatively charged region 112 in the channel layer 104. Besides, the upper gate 204 and the lower gate 200 can include the same or different materials. An enhancement mode HEMT device 12 of the present invention is thus completed.

In an embodiment, an enhancement mode HEMT device 13 is formed when the step of forming the negatively charged region 112 is omitted from the above method upon the process requirements, as shown in FIG. 4.

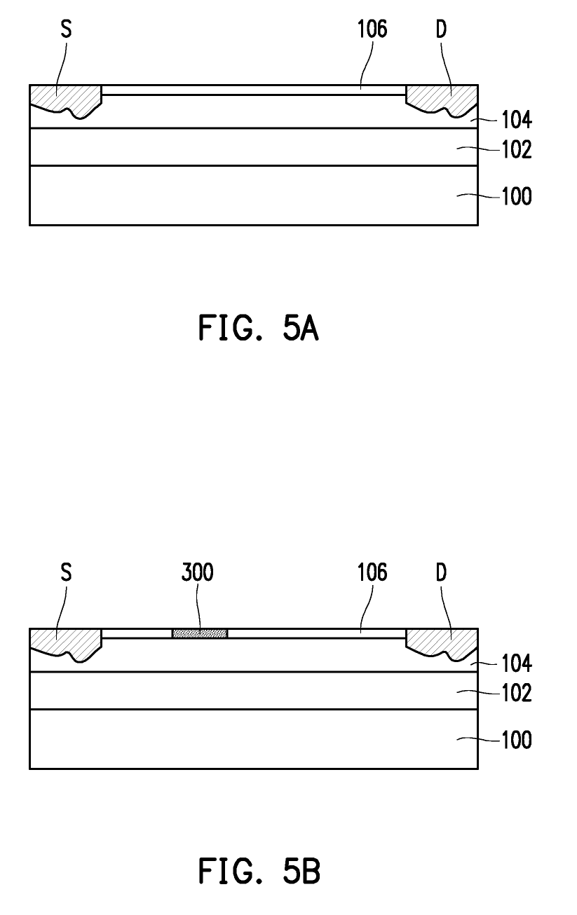

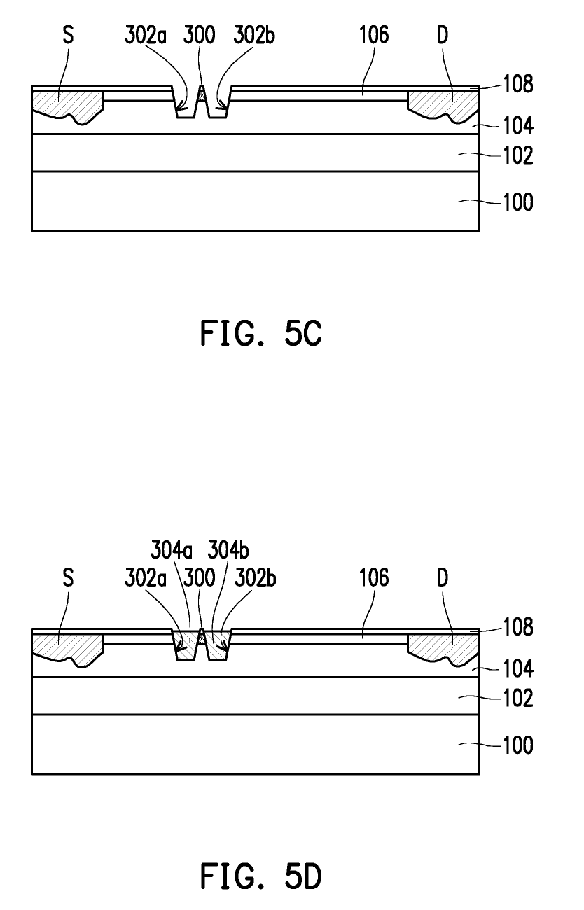

FIG. 5A to FIG. 5E are schematic cross-sectional views of a method of forming an enhancement mode HEMT device according to yet another embodiment of the present invention.

Referring to FIG. 5A, a structure of FIG. 1A is provided. Referring to FIG. 5B, a negatively charged region 300 is formed in the barrier layer 106. In an embodiment, the portion of the barrier layer 106 corresponding to the subsequently formed trenches 302a and 302b is negatively charged. In other words, the negatively charged region 300 is regarded as a part of the barrier layer 106. In an embodiment, the method of forming the negatively charged region 300 includes performing an ion implantation process, wherein the implanting ions include fluorine ions.

Referring to FIG. 5C, a passivation layer 108 is formed on the barrier layer 106. Thereafter, trenches 302a and 302b are formed in the passivation layer 108, the barrier layer 106 and the channel layer 104. In an embodiment, the trenches 302a and 302b penetrate through the passivation layer 108 and the barrier layer 106, and extend into a portion of channel layer 104. In an embodiment, the trenches 302a and 302b are separated from each other, and the negatively charged region 300 is disposed in the barrier layer 106 between the trenches 302a and 302b. In an embodiment, the width of each of the trenches 302a and 302b ranges from about 1 nm to about 10 μm (e.g., from about 0.1 μm to about 5 μm), and the distance between the trenches 302a and 302b is less than or equal to about 1 μm. In an embodiment, the method of forming the trenches 302a and 302b includes performing a patterning process (e.g., photolithography etching processes) to the passivation layer 108, the barrier layer 106 and the channel layer 104.

Referring to FIG. 5D, lower gates 304a and 304b are formed in the trenches 302a and 302b. The material and forming method of the lower gates 304a and 304b are similar to those of the lower gate 200, and the details are not iterated herein.

Referring to FIG. 5E, a dielectric layer 306 is optionally formed on the passivation layer 108 and the lower gates 304a and 304b. Thereafter, an upper gate 308 is formed on the dielectric layer 306. The materials and forming methods of the dielectric layer 306 and the upper gate 308 are similar to those of the dielectric layer 202 and the upper gate 204, and the details are not iterated herein. In an embodiment, the upper gate 308, the dielectric layer 306 and the lower gates 304a and 304b constitute a gate G, wherein the lower gates 304a and 304b are in contact with the 2DEG 105 in the channel layer 104, and the negatively charged region 300 is between the lower gates 304a and 304b. An enhancement mode HEMT device 14 of the present invention is thus completed.

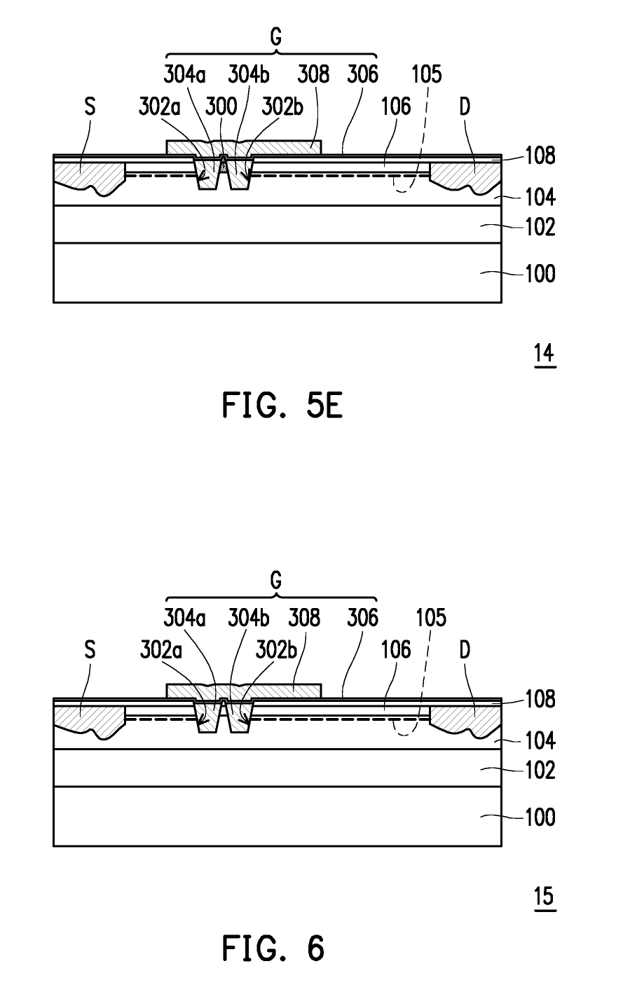

In an embodiment, an enhancement mode HEMT device 15 is formed when the step of forming the negatively charged region 300 is omitted from the above method upon the process requirements, as shown in FIG. 6.

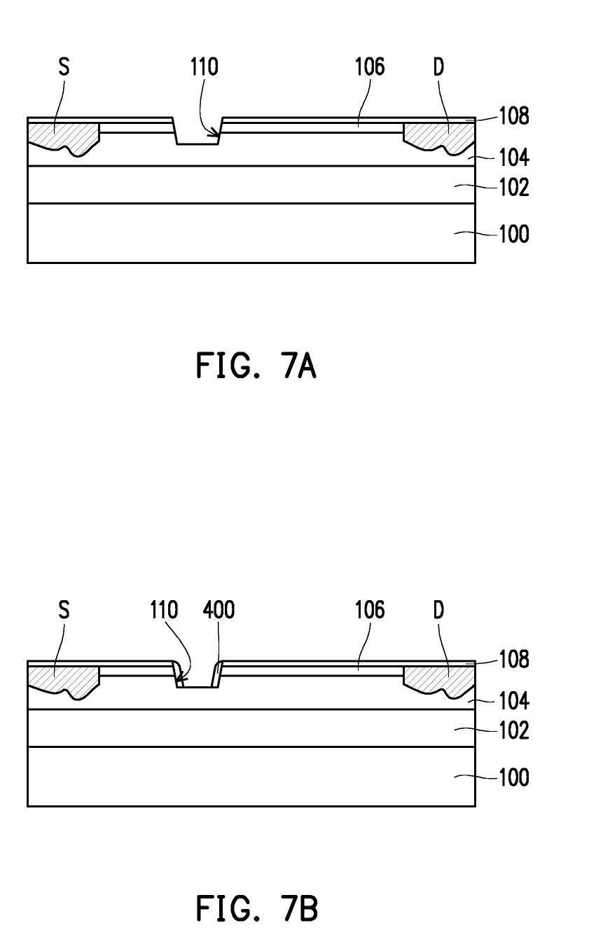

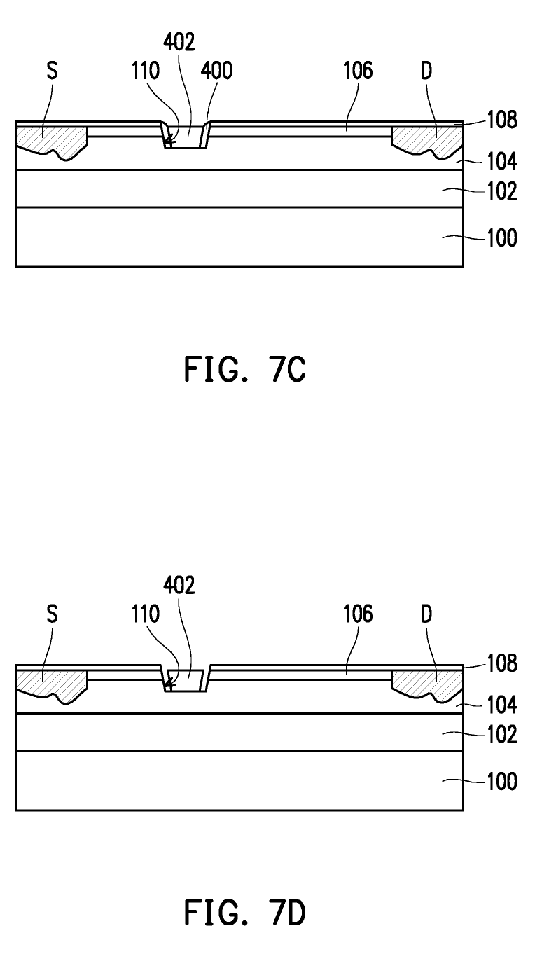

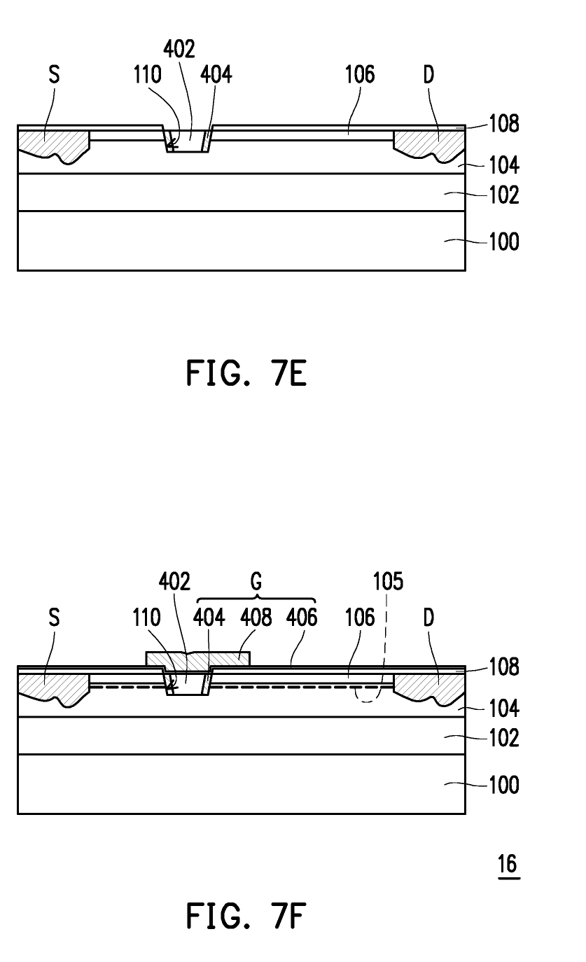

FIG. 7A to FIG. 7F are schematic cross-sectional views of a method of forming an enhancement mode HEMT device according to still another embodiment of the present invention.

Referring to FIG. 7A, a structure of FIG. 1B is provided. Referring to FIG. 7B, a spacer 400 is formed on the sidewall of the trench 110. Specifically, the spacer 400 is formed to cover the sidewall of the trench 110 while expose the bottom of the trench 110. In an embodiment, the spacer 400 includes silicon oxide, silicon nitride, silicon oxynitride or a combination thereof. Besides, the spacer 400 can have a single-layer or multi-layer structure. In an embodiment, the method of forming the spacer 400 includes forming a spacer material layer on the surfaces of the passivation layer 108 and the trench 110, and performing an anisotropic etching process to the spacer material layer.

Referring to FIG. 7C, a barrier layer 402 is formed in the trench 110. In an embodiment, the barrier layer 402 includes a group III nitride or a group III-V compound semiconductor material. In an embodiment, the barrier layer 402 includes AlₓGa_{y}In_{1-x-y}N, x≥0, y≥0, and x+y≤1. In an embodiment, the barrier layer 402 has a zinc blende structure or a non-polar structure. In an embodiment, the method of forming the barrier layer 402 includes performing an epitaxial regrowth process. Specifically, an epitaxial layer is not grown or formed on the sidewall of the trench 110 covered by the spacer 400. Therefore, the bottom of the trench 110 uncovered by the spacer 400 (or the surface of the channel layer 104 exposed by the bottom of the trench 110) can serve as a regrowth surface for forming the barrier layer 402.

Referring to FIG. 7D, the spacer 400 is removed after the epitaxial regrowth process. In an embodiment, the method of removing the spacer 400 includes performing a suitable etching process.

Referring to FIG. 7E, a lower gate 404 is formed in the trench 110. Specifically, the lower gate 404 is formed to surround the barrier layer 402. In an embodiment, the lower gate 404 includes a metal or a metal nitride (such as Ta, TaN, Ti, TiN, W, Pd, Ni, Au, Al or a combination thereof), a metal silicide (such as WSiₓ), or a material which can form a Schottky contact with a group III-V compound semiconductor. In an embodiment, the method of forming the lower gate 404 includes forming a lower gate material layer on the passivation layer 108 and the barrier layer 402, and the lower gate material layer completely fills the trench 110. Thereafter, a CMP process is performed by using the barrier layer 402 as a polishing mask, so as to remove the lower gate material layer outside of the trench 110. In an embodiment, the surface of the lower gate 404 is substantially coplanar with the surface of the barrier layer 402. In an embodiment, the width of the barrier layer 402 ranges from about 1 nm to about 10 μm (e.g., from about 0.1 μm to about 5 μm), and the lower gate 404 in a form of spacer has a width of about 1 nm to about 10 μm (e.g., from about 0.1 μm to about 5 μm).

Referring to FIG. 7F, a dielectric layer 406 is optionally formed on the passivation layer 108 and the lower gate 404. Thereafter, an upper gate 408 is formed on the dielectric layer 406. The materials and forming methods of the dielectric layer 406 and the upper gate 408 are similar to those of the dielectric layer 202 and the upper gate 204, and the details are not iterated herein. In an embodiment, the upper gate 408, the dielectric layer 406 and the lower gate 404 constitute a gate G, wherein the lower gate 404 is in contact with the 2DEG 105 in the channel layer 104, and the lower gate 404 surrounds the barrier layer 402 with a non-polar structure. An enhancement mode HEMT device 16 of the present invention is thus completed.

In each of the enhancement mode HEMT devices of FIG. 1D, FIG. 2, FIG. 3C, FIG. 4, FIG. 5E, FIG. 6 and FIG. 7F, a gate is designed to be in physical contact with a channel layer. Specifically, the turn-on current of the enhancement mode HEMT device is conducted through the gate, so as to improve the electrical difference caused by unstable etching and therefore reduce the turn-on channel resistance of the device. Besides, a negatively charged region or a non-polar structure is disposed aside the lower gate to significantly increase the threshold voltage and effectively reduce the leakage current.

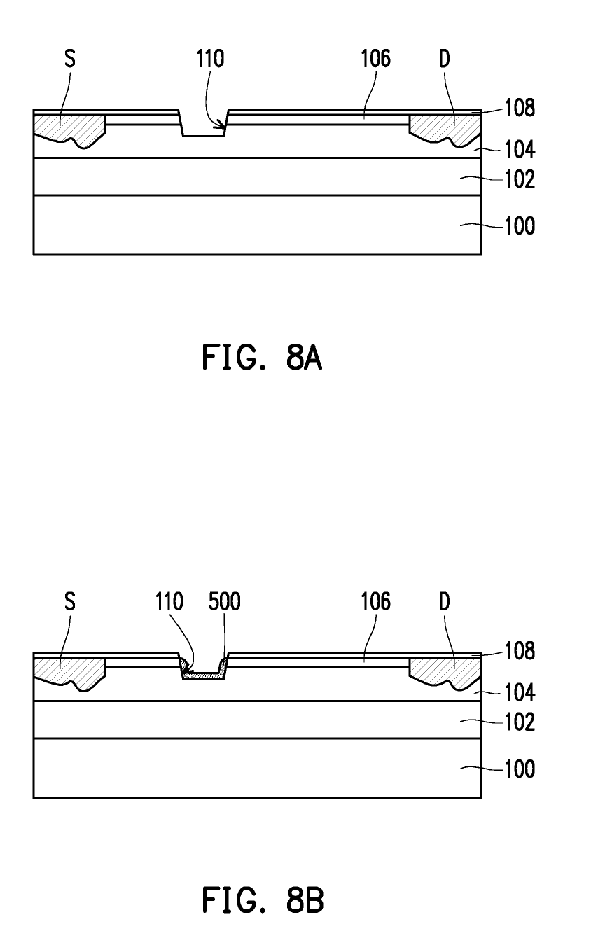

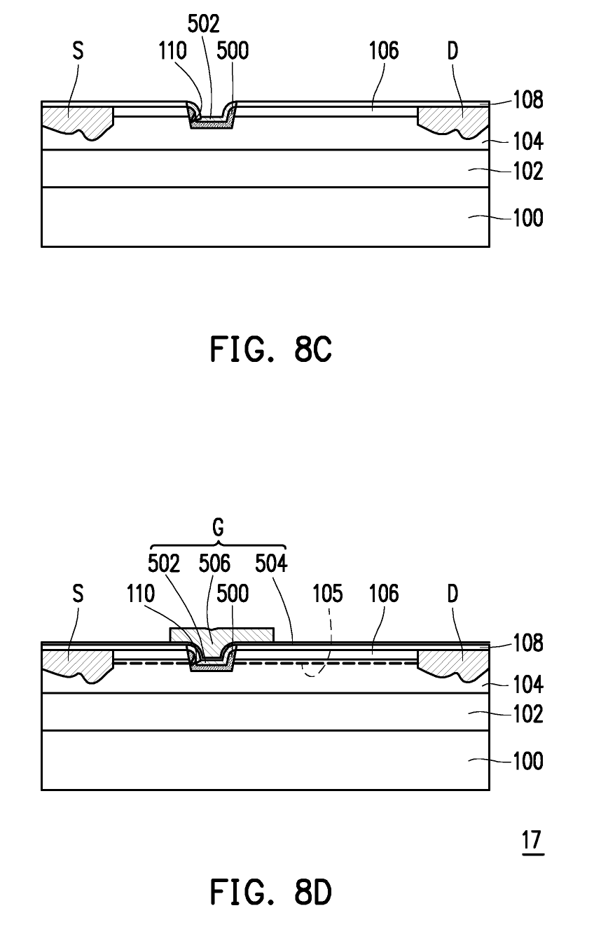

FIG. 8A to FIG. 8D are schematic cross-sectional views of a method of forming an enhancement mode HEMT device according to an embodiment of the present invention.

Referring to FIG. 8A, a structure of FIG. 1B is provided. Referring to FIG. 8B, a barrier layer 500 is formed in the trench 110. In an embodiment, the barrier layer 500 includes a group III nitride or a group III-V compound semiconductor material. In an embodiment, the barrier layer 500 includes AlₓGa_{y}In_{1-x-y}N, x≥0, y≥0, and x+y≤1. In an embodiment, the barrier layer 500 has a zinc blende structure or a non-polar structure. In another embodiment, barrier layer 500 has a wurtzite structure or a polar structure. In an embodiment, the method of forming the barrier layer 500 includes performing an epitaxial regrowth process. Specifically, the sidewall and the bottom of the trench 110 uncovered by the passivation layer 108 (or the surfaces of the channel layer 104 and the barrier layer 106 exposed by the sidewall and the bottom of the trench 110) can serve as a regrowth surface for re-growing the barrier layer 500 on the sidewall and bottom of the trench 110. In an embodiment, in the epitaxial regrowth process, an ion implantation process in which implanting ions include fluorine ions can be simultaneously preformed, so the barrier layer 500 is regrown as a negatively charged barrier layer 500.

Referring to FIG. 8C, a lower gate 502 is formed on the barrier layer 500 in the trench 110. The material and forming method of the lower gate 502 are similar to those of the lower gate 200, and the details are not iterated herein.

Referring to FIG. 8D, a dielectric layer 504 is optionally formed on the passivation layer 108 and the lower gate 502. Thereafter, an upper gate 506 is formed on the dielectric layer 504. The materials and forming methods of the dielectric layer 504 and the upper gate 506 are similar to those of the dielectric layer 202 and the upper gate 204, and the details are not iterated herein. In an embodiment, the upper gate 506, the dielectric layer 504 and the lower gate 502 constitute a gate G. An enhancement mode HEMT device 17 of the present invention is thus completed.

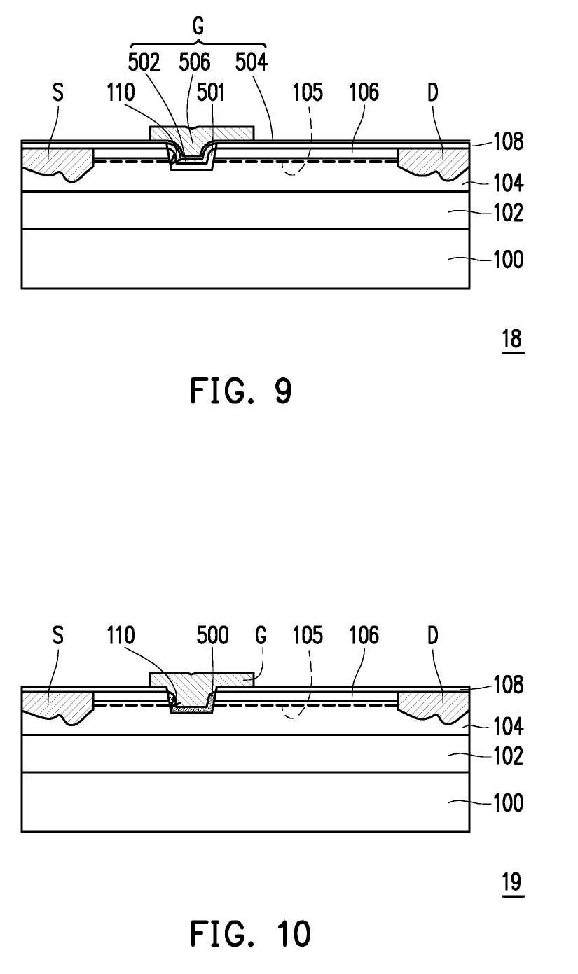

In an embodiment, an enhancement mode HEMT device 18 is formed when a non-charged barrier layer 501 is formed instead of the barrier layer 500 upon the process requirements, as shown in FIG. 9.

In an embodiment, an enhancement mode HEMT device 19 is formed when the step of forming the dielectric layer 504 is omitted from the above method upon the process requirements, as shown in FIG. 10. In an embodiment, the gate G is in physical contact with the barrier layer 500.

In each of the enhancement mode HEMT devices of FIG. 8D, FIG. 9 and FIG. 10, a high barrier material is disposed between a gate and a channel layer to significantly increase the threshold voltage and effectively reduce the leakage current.

Some structures of the invention are illustrated below with reference to FIG. 1D, FIG. 2, FIG. 3C, FIG. 4, FIG. 5E, FIG. 6 and FIG. 7F. In an embodiment, the present invention provides an enhancement mode HEMT device 10/11/12/13/14/15/16 that includes a substrate 100, a channel layer 104, a barrier layer 106, a gate G, a source S and a drain D. The channel layer 104 is disposed on the substrate 100. The barrier layer 106 is disposed on the channel layer 104. At least one trench 110/302a/302b penetrates through the barrier layer 106 and extends into the channel layer 104. In an embodiment, the bottom of the at least one trench 110/302a/302b is lower than the 2DEG 105 in the channel layer 104. The gate G is disposed on the barrier layer 104, fills in the at least one trench 110/302a/302b and contacts the channel layer 104. The source S and the drain D are disposed in the barrier layer 106 and the channel layer 104 and located at two sides of the gate G. In an embodiment, the source S and the drain D are electrically connected to the 2DEG 105 in the channel layer 104.

In an embodiment, the enhancement mode HEMT device 10/12 further includes a negatively charged region 112 disposed in the channel layer 104 and surrounding the sidewall and the bottom of the at least one trench 110. The negatively charged region 112 includes fluorine ions.

In an embodiment, in the enhancement mode HEMT device 14/15, the at least one trench includes trenches 302a and 302b separated from each other, and the distance between the trenches 302a and 302b is less than or equal to about 1 μm. In an embodiment, the enhancement mode HEMT device 14 further includes a negatively charged region 300 disposed in the channel layer 104 between the trenches 302a and 302b.

In an embodiment, the enhancement mode HEMT device 10/11/12/13/14/15/16 further includes a passivation layer 108 disposed between the gate G and the barrier layer 104. Specifically, the passivation layer 108 is disposed between the upper gate of the gate G and the barrier layer 104. In an embodiment, the passivation layer 108 includes silicon oxide, silicon nitride, silicon oxynitride or a combination thereof.

In an embodiment, in the enhancement mode HEMT device 12/13/14/15/16, the gate G includes a lower gate 200/304a/304b/404, a dielectric layer 202/306/406 and an upper gate 204/308/408. The lower gate 200/304a/304b/404 is disposed in the at least one trench 110/302a/302b, the upper gate 204/308/408 is disposed on the lower gate 200/304a/304b/404, and the dielectric layer 202/306/406 is disposed between the lower gate and the upper gate. The dielectric layer 202/306/406 includes aluminum oxide. In an embodiment, the dielectric layer 202/306/406 is further disposed between the upper gate 204/308/408 and the barrier layer 106. Besides, the passivation layer 108 is disposed between the dielectric layer 202/306/406 and the barrier layer 106.

In an embodiment, the enhancement mode HEMT device 16 further includes a barrier layer 402 disposed in the at least one trench 110 and surrounded by the lower gate 404. The barrier layer 402 has a zinc blende structure. The barrier layer 402 includes AlₓGa_{y}In_{1-x-y}N, x≥0, y≥0, and x+y≤1.

The alternative structures of the present invention are illustrated below with reference to FIG. 8D, FIG. 9 and FIG. 10. In an embodiment, the present invention provides an enhancement mode HEMT device 17/18/19 that includes a substrate 100, a channel layer 104, a barrier layer 106, a barrier layer 500/501, a gate G, a source S and a drain D. The channel layer 104 is disposed on the substrate 100. The barrier layer 106 is disposed on the channel layer 104, wherein at least one trench 110 penetrates through barrier layer 106 and extends into channel layer 104. The gate G is disposed on the barrier layer 106 and fills in the at least one trench 110. In an embodiment, the gate G includes a lower gate 502, a dielectric layer 504 and an upper gate 506. The lower gate 502 is disposed in the at least one trench 110, the upper gate 506 is disposed on the lower gate 502, and the dielectric layer 504 is disposed between the lower gate 506 and the upper gate 502.

The barrier layer 500/501 is disposed between the gate G and the channel layer 104. The barrier layer 500/501 has a zinc blende structure or a wurtzite structure. The barrier layer 500/501 includes AlₓGa_{y}In_{1-x-y}N, x≥0, y≥0, and x+y≤1. In an embodiment, the barrier layer 500 is negatively charged. In another embodiment, the barrier layer 501 is not charged. The source S and the drain D are disposed in the barrier layer 106 and the channel layer 104 and located at two sides of the gate G. In an embodiment, the source S and the drain D are electrically connected to the 2DEG 105 in the channel layer 104.

In summary, in some embodiments, a gate is designed to be in physical contact with a channel layer in an enhancement mode HEMT device. Specifically, the turn-on current of the enhancement mode HEMT device is conducted through the gate, so as to improve the electrical difference caused by unstable etching and therefore reduce the turn-on channel resistance of the device. In alternative embodiments, a negatively charged region, a non-polar structure or a high barrier material is disposed aside a lower gate in another enhancement mode HEMT device, and such disposition can significantly increase the threshold voltage and effectively reduce the leakage current.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. An enhancement mode HEMT device, comprising:
a channel layer, disposed on a substrate;
a first barrier layer, disposed on the channel layer, wherein at least one trench penetrates through the first barrier layer and extends into the channel layer;
a gate, disposed on the first barrier layer, filling in the at least one trench and contacting the channel layer; and
a source and a drain, disposed in the first barrier layer and the channel layer and located at two sides of the gate.

2. The enhancement mode HEMT device of claim 1, further comprising a negatively charged region disposed in the channel layer and surrounding a sidewall and a bottom of the at least one trench.

3. The enhancement mode HEMT device of claim 2, wherein the negatively charged region comprises fluorine ions.

4. The enhancement mode HEMT device of claim 1, further comprising a passivation layer disposed between the gate and the first barrier layer.

5. The enhancement mode HEMT device of claim 4, wherein the passivation layer comprises silicon oxide, silicon nitride, silicon oxynitride or a combination thereof.

6. The enhancement mode HEMT device of claim 1, wherein the gate comprises:
a lower gate, disposed in the at least one trench; and
an upper gate, disposed on the lower gate,
wherein a dielectric layer is disposed between the lower gate and the upper gate.

7. The enhancement mode HEMT device of claim 6, further comprising a second barrier layer disposed in the at least one trench and surrounded by the lower gate.

8. The enhancement mode HEMT device of claim 7, wherein the second barrier layer has a zinc blende structure.

9. The enhancement mode HEMT device of claim 7, wherein the second barrier layer comprises AlₓGa_{y}In_{1-x-y}N, x≥0, y≥0, and x+y≤1.

10. The enhancement mode HEMT device of claim 6, wherein the dielectric layer comprises aluminum oxide.

11. The enhancement mode HEMT device of claim 6, wherein the dielectric layer is further disposed between the upper gate and the first barrier layer.

12. The enhancement mode HEMT device of claim 6, further comprising a passivation layer disposed between the dielectric layer and the first barrier layer.

13. The enhancement mode HEMT device of claim 1, wherein the at least one trench comprises two trenches separated from each other, and a distance between the two trenches is less than or equal to 1 μm.

14. The enhancement mode HEMT device of claim 13, further comprising a negatively charged region disposed in the channel layer between the two trenches.

15. An enhancement mode HEMT device, comprising:
a channel layer, disposed on a substrate;
a first barrier layer, disposed on the channel layer, wherein at least one trench penetrates through the first barrier layer and extends into the channel layer;
a gate, disposed on the first barrier layer and filling in the at least one trench;
a second barrier layer, disposed between the gate and the channel layer; and
a source and a drain, disposed in the first barrier layer and the channel layer and located at two sides of the gate.

16. The enhancement mode HEMT device of claim 15, wherein the second barrier layer has a zinc blende structure.

17. The enhancement mode HEMT device of claim 15, wherein the second barrier layer has a wurtzite structure.

18. The enhancement mode HEMT device of claim 15, wherein the second barrier layer is negatively charged.

19. The enhancement mode HEMT device of claim 15, wherein the second barrier layer is not charged.

20. The enhancement mode HEMT device of claim 15, wherein the gate comprises:
a lower gate, disposed in the at least one trench; and
an upper gate, disposed on the lower gate,
wherein a dielectric layer is disposed between the lower gate and the upper gate.
